(19) United States
(12) Patent Application Publication
(10) Pub. No.: US 2006/0234484 A1
(43) Pub. Date: Oct. 19, 2006

(54) METHOD AND STRUCTURE FOR ION IMPLANTATION BY ION SCATTERING

(75) Inventors: Louis D. Lanzerotti, Burlington, VT (US); David C. Sheridan, Williston, VT (US); Steven H. Voldman, South Burlington, VT (US)

Correspondence Address: GREENBLUM & BERNSTEIN, P.L.C., 1950 ROLAND CLARK DRIVE, RESTON, VA, 20191, US

(73) Assignee: INTERNATIONAL BUSINESS MACHINES CORPORATION, Armonk, NY (US)

(21) Appl. No.: 10/907,752

(22) Filed: Apr. 14, 2005

(51) Int. Cl. H01L 21/22; H01L 21/38

(52) U.S. Cl. 438/556; 438/542; 438/560

(57) ABSTRACT

A scatter-implant process and device is provided where a bi-level doping pattern is achieved in a single doping step. Additionally, devices having different breakdown voltages can be produced in a single implant process. The scatter-implant is fabricated by scattering implant ions off the edge of a mask, thereby reducing the ion energy causing the ions to doping shallower regions than the non-scattered ions which dope a lower region. By adjusting various parameters of the doping process such as, for example, ion type, ion energy, mask type and geometry, in a position of scattering edge relative to other structure of the device, the scatter-implant can be tuned to achieve certain properties of the semiconductor device. Additionally, circuits can be made using the scatter-implant process where pre-selected portion of the circuit incorporate the scatter-implant region and other portions of the circuit do not rely on the scatter region.

### FIELD OF THE INVENTION

The invention relates to doping a substrate, and more particularly to doping a substrate by passing the dopant through a scattering layer.

### BACKGROUND DESCRIPTION

As semiconductor devices have been reduced in size, certain effects which were inconsequential at larger device sizes become problematic at smaller device sizes. For example, where regions in a particular device are formed by implanting ions in a doping process, the ions are typically deposited from directly above the region to be implanted. Additionally, the ions typically will travel a certain distance through a material before losing energy and coming to a stop thereby forming a doped region. As an example, during the formation of an implanted sub-collector, ions are deposited from directly above the region to form the implanted sub-collector. In this example, the ions will travel through a predetermined amount of material before lodging in a region in the material to form the implanted sub-collector.

Typically, the regions where no doping is required are protected by a mask during the implantation process. Openings are formed in the mask which correspond to the regions to be implanted, and thus a region to be implanted will be surrounded by a mask edge. The mask portion of the substrate and the exposed portion of the substrate are blanket exposed to ions during implantation. A certain portion of the ions will fall on the mask and be absorbed by the mask thereby being blocked from entering the substrate. Some ions will impinge upon the unmasked regions of the substrate and travel through the substrate to form the doped region at a predetermined depth within the substrate. Other ions will strike the mask very close to the mask edge.

Those ions that strike the mask close to the mask edge will scatter off the molecules or scattering centers forming the mask. Scattered ions will then have their direction of travel changed by the scattering centers. A certain portion of the scattered ions will be scattered at an angle such that they will pass out of the mask by traveling through the edge of the mask and thereby enter unmasked portions of the substrate. Because the such ions have been scattered, they will enter the substrate with less energy then the ions which entered the substrate without passing through the mask.

Due to having less energy, the scattered ions entering the substrate will not penetrate into the substrate as far and will form an unwanted doped region near the surface of the substrate. In situations where the unwanted doped regions near the surface of the substrate coincides with an active region of the device, the unwanted doping can introduce negative characteristics to the completed device. Accordingly, it is typical for a second low energy doping process to be implemented to neutralize the unwanted doping near the surface of the substrate.

### SUMMARY OF THE INVENTION

In a first aspect of the invention, a method of configuring a breakdown voltage of a semiconductor device includes the steps of configuring a scattering edge to scatter ions into a region to be scatter-implanted, wherein the region to be scatter-implanted is a prescribed distance from the scattering edge. The method also includes passing a dose of ions through the scattering edge, and scattering a portion of the dose of ions from the scattering edge into the region to be scatter-implanted.

In another aspect of the invention, a method of bi-level implanting includes arranging a scattering edge on a substrate, and forming a lower region of a bi-level implant by directing s single dose of ions into the scattering edge and into a lower layer of the substrate. The method also includes forming an upper region of the bi-level implant by scattering ions of the single does of ions from the scattering edge into an upper layer of the substrate.

In another aspect of the invention, a semiconductor device includes ions of a single dose direct-implanted in a substrate at a lower level, and ions of the single dose scatter-implanted in the substrate above the direct-implanted ions.

### BRIEF DESCRIPTION OF THE DRAWINGS

FIG. 1 illustrates a bi-level implantation process in accordance with the invention;

FIG. 2 illustrates a bi-level implant in accordance with the invention;

FIG. 3 illustrates a device having a bi-level implant in accordance with the invention;

FIG. 4 illustrates a scatter-implant process in accordance with the invention;

FIG. 5 illustrates a scatter-implant process in accordance with the invention;

FIG. 6 illustrates a scatter-implant process in accordance with the invention; and

FIGS. 7A-F illustrate circuits incorporating a device having a scatter-implant region in accordance with the invention.

### DETAILED DESCRIPTION OF EMBODIMENTS OF THE INVENTION

The invention produces semiconductor devices having different break down voltages in a single ion implantation process. Thus, the invention can provide semiconductor devices and circuits incorporating the semiconductor devices where one particular device has a lower breakdown voltage than another particular device formed during a single doping step. Thus, the invention allows semiconductor devices to be fabricated with different breakdown voltages in one ion implantation operation. This is accomplished by forming a bi-level implantation using a scatter implantation process. For example, the scatter implantation process of the invention can rely on the edge of the mask to scatter ions into an adjacent unmasked substrate where the scattered ions have a lower energy than non-scattered ions. The low energy ions will be deposited near the surface of the substrate while the higher energy non-scattered ions will be deposited at a greater depth in the substrate.

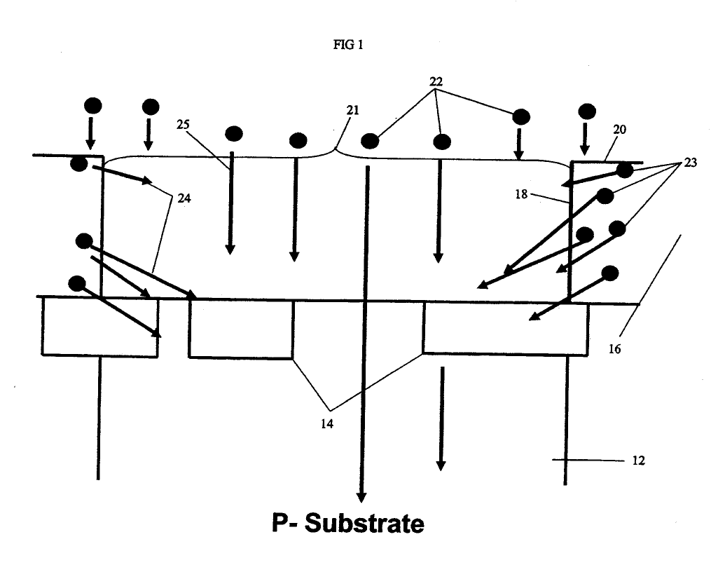

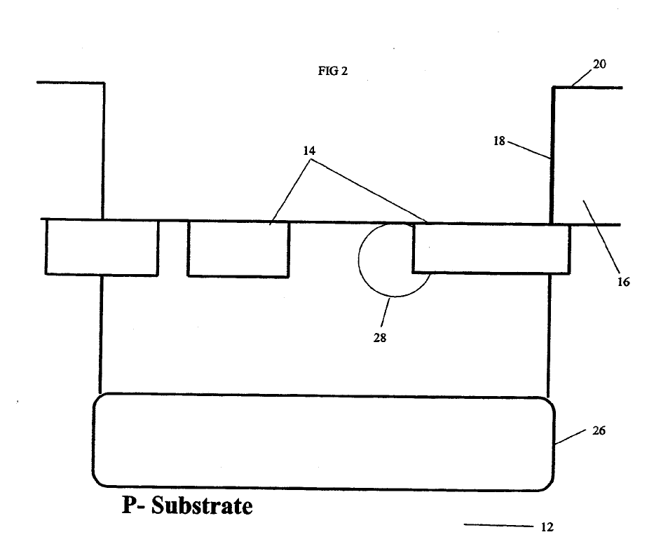

Referring to FIG. 1, a scatter-implant process is shown. In the scatter-implant process, a p-substrate 12 has a mask 20 on its surface. The mask 20 has an opening or hole 21 through it which exposes the surface of the p-substrate 12. Also included in the p-substrate 12 are shallow trench isolations (STI) 14. During the scatter implantation process, one portion of ions 22 passes directly through the hole 21 of the mask 20 following non-scatter paths 25 to be deposited within the p-substrate 12 to eventually form a deep implant therein. Another portion of the ions 22 strike the mask 20 near an edge 18 of the mask 20. Another portion of the ions 22 striking the mask 20 will penetrate part way through the mask 20 and scatter resulting in scattered ions 23 following scatter paths 24. For example, molecules forming the mask 20 towards the edge 18 of the mask 20 may produce the scattered ions 23. After being scattered in the mask 20, a portion of those scattered ions 23 will pass out of the mask 20 through the edge 18 of the mask 20 towards the surface of the substrate 12. Those scattered ions 23 will penetrate to a relatively shallow depth within the substrate 12. Accordingly, because the scattered ions 23 have passed through a portion of the mask 20 before entering the p-substrate 12, those scattered ions 23 will have a lower energy and penetrate less than the ions 22 that passed directly into the p-substrate 12.

It should be noted that the scattered ions 23 will scatter off of the mask 20 non-randomly with a scatter angle having a Gaussian distribution around a mean scattering angle. The mean scattering angle depends on various factors such as mask composition, ion compensation, and ion energy. Accordingly, various parameters of the scatter implantation process may be carefully controlled in order to direct the scattered ions into a pre-selected area of the p-substrate 12. For example, the energy level and composition of the scattered ions 23 may be selected to achieve a particular mean scattering angle and Gaussian distribution. Additionally, the edge 18 of the mask 20 can be positioned or angled in a pre-determined way in order to direct the majority of scattered ions 23 into a predetermined region of the p-substrate 12.

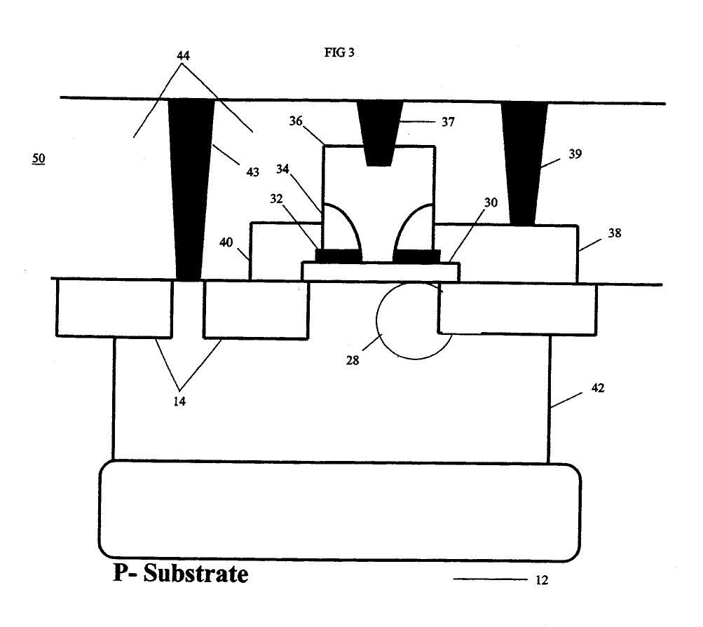

Referring to FIG. 2, the structure of FIG. 1 is shown after the scatter-implant process, where the p-substrate 12 has received a deep implant of ions 22 forming an implanted sub-collector 26. Additionally, the p-substrate 12 has received a shallower implant of scattered ions 23, which has formed a scatter-implant 28. It should be noted that the scattered ions 23 will have a Gaussian distribution around a certain mean energy level as well as the Gaussian distribution around a mean scatter angle, and thus, the depth of the scattered ions will have a Gaussian distribution around a certain mean depth depending on the various parameters of the scatter implantation process. Accordingly, the scatter-implant 28 will be positioned shallower in the p-substrate 12 in comparison to the depth of the implanted sub-collector 26. By adjusting one or more scattering parameters, such as, for example the type, velocity or angle of ions, the position, angle, thickness or composition of the edge 18 of the mask 20, the horizontal and vertical positioning, size, distribution, etc. of the scatter implantation 28 may be adjusted as desired.

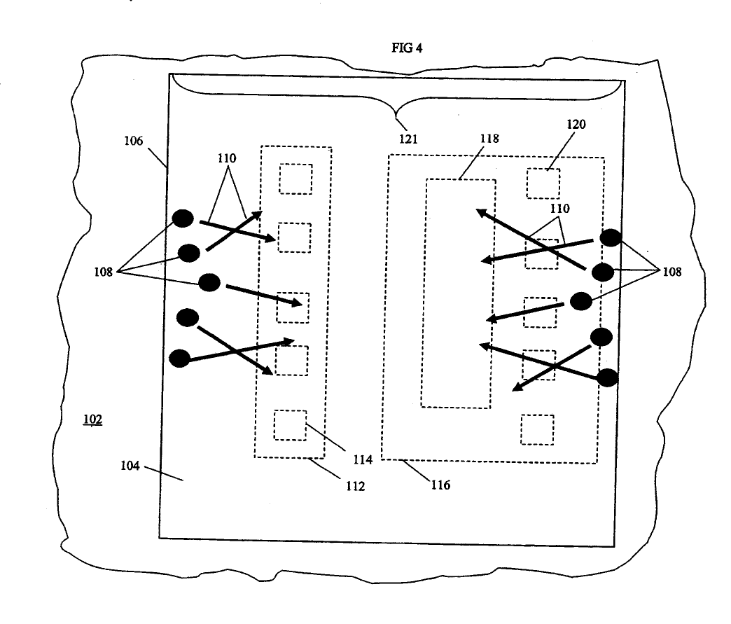

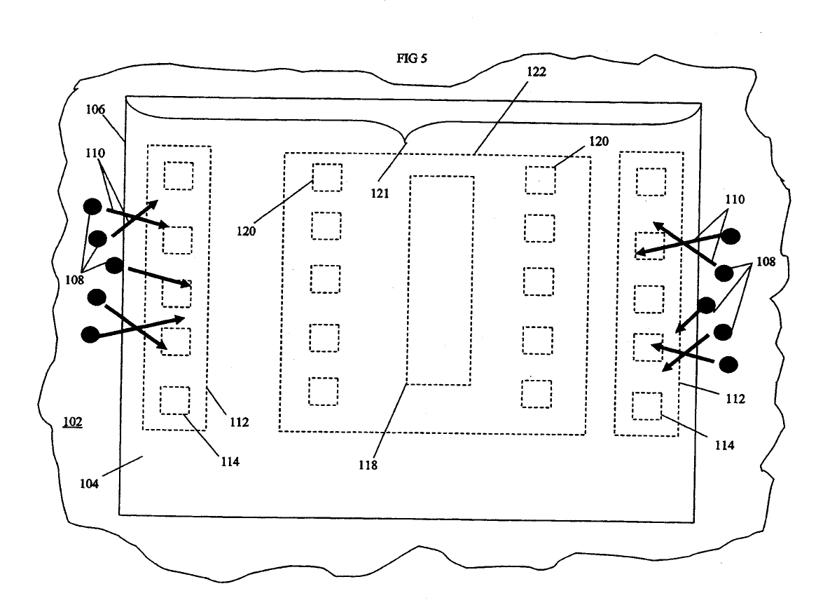

Referring to FIG. 3, a completed semi-conductor device 50 is shown incorporating the scattered implant or scatter-implant 28. Thus, the completed device 50 includes a p-substrate 12 having an implanted sub-collector 26 and a shallower scattered implant 28. The semiconductor device 50 also includes a n-epitaxy/well 42. At the top of the p-substrate 12 and n-epitaxy/well 42 regions are the three STIs 14. Additionally, at the top of the n-epitaxy/well 42 and next to an STI region 14, is the scatter-implant 28. Above the scatter-implant 28 on top of the n-epitaxy/well 42 is an epitaxial silicon germanium base 30. Additionally, on top of the epitaxial silicon germanium (SiGe) base 30 is an emitter 36. Also on top of the epitaxial silicon germanium (SiGe) base 30 are dielectric films 32, and silicon dioxide mandrel 34.

Next to one side of the epitaxial silicon germanium (SiGe) base 30 is a base contact 38, and next to the other side of the epitaxial silicon germanium base 30 is a collector contact 40. Above the n-epitaxy/well 42 and STI regions 14 is deposited an inter-layered dielectric (ILD) 44. Additionally, a collector via 43, emitter via 37, and base via 39 are formed to complete the device. Accordingly, the device 50 is formed having an implanted sub-collector 26 and a scatter-implant 28 in one implantation process. Consequently, the implanted sub-collector 26 and the scatter-implant 28 are two implant regions formed in a single implantation process and may be referred collectively to as a bi-level implant.

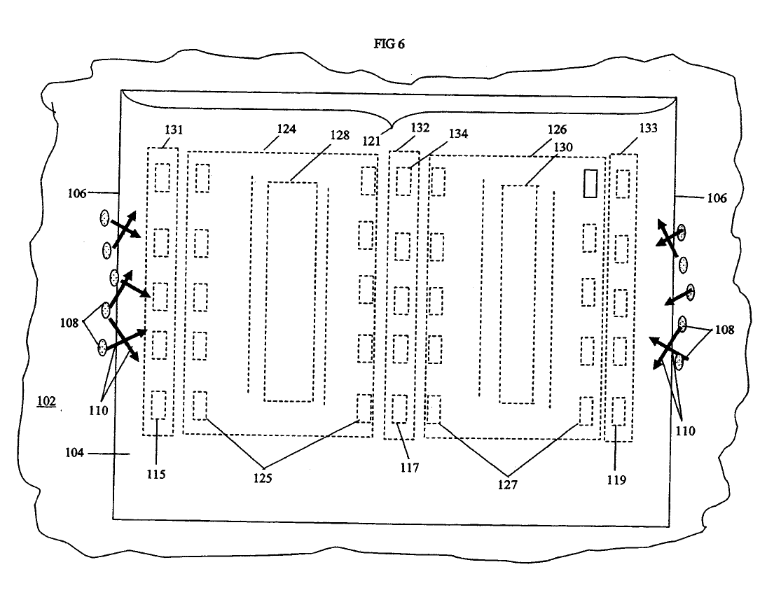

Referring to FIG. 4, a top view of the scattering process is shown. A mask 102 has a hole 121 therein which exposes a portion of a substrate 104. Implant ions scatter off an edge 106 of the mask 102 to become scattered ions 108. The scattered ions 108 follow deflected paths 110 to be placed in an upper surface of the substrate 104. Subsequently, a collector contact 112 with contacts 114 will be formed on the substrate 104 and a base contact 116 with contacts 120, and an emitter 118 will be formed on the substrate 104. Accordingly, FIG. 4 shows ions which would otherwise travel in a linear direction to be deposited at a lower depth in a substrate, are deflected at an angle by a mask edge to be deposited at a shallower depth in a region corresponding to the planned location of certain surface structures of the semiconductor device.

Referring to FIG. 5, a view of the scattering process for a semiconductor device having a collector-base-emitter-base-collector (CBEBC) structure is shown. The structure includes a mask 102 having an opening 121 to expose a substrate 104. Ions 108 are then scattered off the edge 106 of the mask 102 to be implanted into the substrate 104. The scattered ions 108 follow deflected paths 110 which are paths, which deviate from the uninterrupted path the ions would follow if they did not scatter. The scattered ions 108 are implanted in addition to unscattered ions into the substrate 104 and thus form a bi-level implant where the unscattered ions form a lower implant region and the scattered ions 108 form a shallow implant region.

Subsequent to the scatter implant, a collector contact 112 with contacts 114, and a two-sided base 122 on either side of an emitter 118 is added. The two-sided base 122 has contacts 120, and a second collector 112 having collector contacts 114 is added on the right side of the hole 121 in the mask 102. Accordingly, a collector-base-emitter-base-collector (CBEBC) structure is formed and the emitter region of the CBEBC structure has a bi-level implant having a deeper implant region and a shallow implant region simultaneously formed in one implant process. Any device which may benefit from a bi-level implant may be fabricated using a scatter-implant process, such as, for example, a collector-emitter-base (CEB) structure, a collector-base-emitter (CBE) structure, or a collector-emitter-base-emitter-collector (CEBEC) structure.

Referring to FIG. 6, a mask 102 has a hole 121 therein exposing a substrate 104. Scattered ions 108 are scattered off the edges 106 of the mask 102. The scattered ions 108 follow deflected paths 110 to be implanted at a relatively shallow depth within the substrate 104. Additionally, unscattered ions travel relatively straight paths to become implanted at a deeper depth within the substrate 104. Subsequently, two semiconductor devices, each having a CBEBC structure may be formed on the substrate 104. Specifically, three collector contacts 131, 132 and 133 are formed on the substrate 104 with two base contacts 124 and 126 arranged between each collector contact 131, 132, and 133 respectively. Near the center of each base contact 124 and 126 are first and second emitters 128 and 130.

The three collector contacts 131, 132 and 133 have respective contacts 115, 117 and 119. On each side of each base contact 124 and 126 are contacts 125 and 127, respectively. Accordingly, each base contact 124 and 126 has an emitter 128 and 130, respectively. Each respective emitter 128 and 130 has a particular width and position relative to the scatter-implant in the substrate 104. For example, the first emitter 128 can have a wider width and thus, overlay the scatter-implant in the substrate 104. The second emitter 130 can have a narrower width and thus, be to the side and have less overlap of the respective scatter-implant in the substrate 104.

Accordingly, the first emitter 128 will have the scatter-implant region in its active region and thus have a reduced breakdown voltage. Conversely, the second emitter 130 is positioned so that the scatter-implant region is not in the active region and will thus have a higher breakdown voltage. As can be seen, the side-by-side CBEBC and CBEBC structure of FIG. 6A allows two semi conductor devices, each one having a different breakdown voltage, to be simultaneously formed in one implantation process. In the process, a first portion of implant ions are directly implanted into a deeper region of the substrate and a second portion of implant ions are scatter-implanted into a shallower region of the substrate.

Sub-collector resist induced scattering effects may lead to modulation of the breakdown voltage in high energy implanted MeV single sided collector SiGe transistors. This effect is not evident in the two-sided collector SiGe transistors. Such difference are due to layout geometry and resulting scattering effects during implantation. This feature produces a low breakdown single sided SiGe transistor, and a high breakdown double-sided collector SiGe transistor with one subcollector implant. This process/layout produces the non-optimum conditions in the non-optimum transistor for functionality, but is an advantage in other circuits, such as, for example, an ESD protection network.

Embodiments of the invention utilize both a low breakdown single sided implant MeV sub-collector SiGe NPN transistor for a trigger element to protect the high breakdown element. As such, the low breakdown single-sided implanted bus collector is utilized as a trigger element for the high breakdown two-sided collector SiGe NPN for the discharge network. In this configuration, a low breakdown trigger is small and a high breakdown device which has a low collector resistance is provided. Such a configuration achieves a two transistor breakdown characteristic with a single implant step using a single sided versus a double-sided implant. The single step implant produces a bi-level implant through a scattering process.

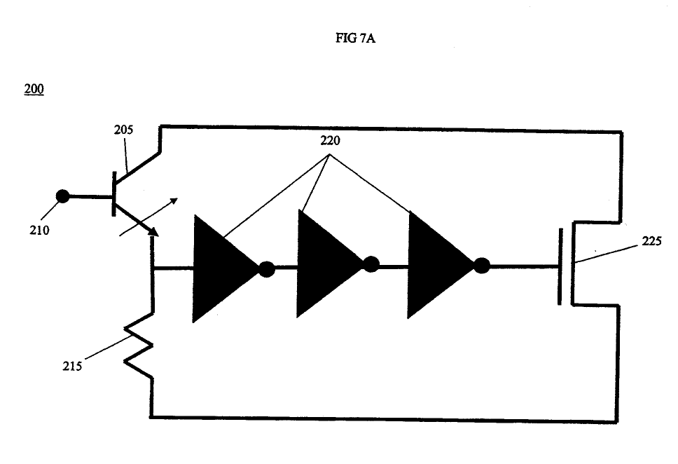

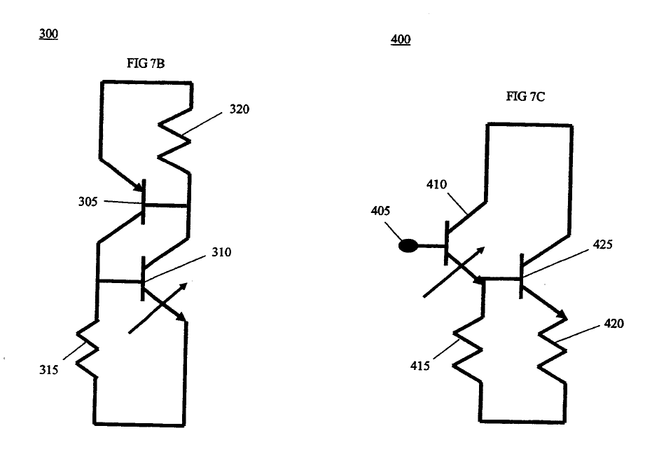

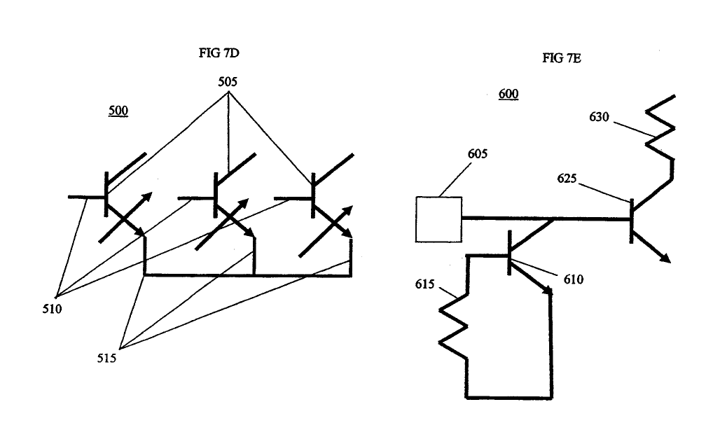

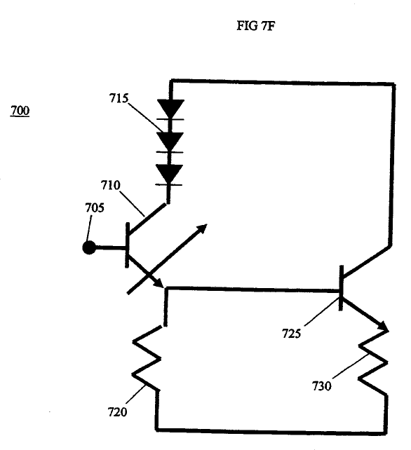

FIGS. 7A-7F are examples of circuits incorporating semiconductor devices fabricated using a scatter-implant process to form a bi-level implant in one implantation step. For example, FIG. 7A shows a scatter-implanted NPN trigger electrostatic discharge (ESD) clamp 200. The ESD clamp 200 includes a NPN transistor 205 having an input 210. The output of the NPN transistor 205 leads to a resistor 215 and a series of CMOS inverters functioning as a gate drive circuit 220. The final output of the series of CMOS inverters 220 leads to CMOS device 225. In this example of an ESD clamp 200, at least the NPN transistor 205 may include a bi-level implant fabricated using a single step scatter-implant process. The ESD power clamp can be placed between power rails.

Referring to FIG. 7B, a SiGe pnpn or SiGe silicon controlled rectifier (SCR) with variable trigger 300 is shown. The SCR 300 includes a PNP transistor 305 and a triggered NPN transistor 310. Also included is a first resistor 315 and a second resistor 320. The base of the PNP transistor 305 is connected to one end of the second resistor 320 and the other end of the second resistor 320 is connected to the collector of the PNP transistor 305. The base of the NPN transistor 310 is connected to the collector of the PNP transistor 305 and the end of the first resistor 315 is connected to the collector of the PNP transistor 305. The second end of the second resistor 315 is connected to the emitter of the NPN transistor 310. This network can be placed on input circuit nodes, or between power supply rails.

In this example of an SCR with variable triggers, at least the PNP transistor 305 or the NPN transistor 310 may include a bi-level implant fabricated using a single step scatter-implant process. Such an SCR with variable trigger 300 offers the advantages of a one-sided collector, a low breakdown voltage, and a lower trigger voltage.

Referring to FIG. 7C, a scatter-circuit ESD application 400 is shown. The trigger side of the scatter-circuit ESD includes an NPN transistor 410 with an emitter connected to a first side of a first resistor 415. The clamp side of the scatter circuit 400 includes a second NPN transistor 425 with it's base connected to the emitter of the first NPN transistor 410, and the collector of the second NPN transistor 425 is connected to a first side of a second resistor 420. A second side of the first resistor 415 is connected to the second side of the second resistor 420. The collector of the second NPN transistor 425 is connected to the collector of the first NPN transistor 410.

In this example of a scatter-implant circuit ESD 400, at least the NPN transistor 410 may include a bi-level implant fabricated using a single step scatter-implant process. Such a circuit offers the advantages of the trigger having a one-sided collector with a low breakdown voltage and a lower trigger voltage, and smaller area. Additionally, the scatter-implant circuit ESD 400 offers the advantages of the clamp having a two-sided collector with a high breakdown voltage and a low resistance collector. Additionally, advantages include functioning as a lower resistant shunt.

Referring to FIG. 7D, a scatter-implant multi-finger tunable NPN circuit 500 is shown. The tunable NPN circuit 500 includes a series of three NPN resistors 505, each having a base 510 and emitter 515. The emitter 515 of each NPN transistor 505 are connected to one another in parallel.

In this example of scatter-implant multi-figures turnable NPN circuit, any one of the series of three NPN transistors 505 may include a bi-level implant fabricated using a single step scatter-implant process. The advantages of such a circuit includes having a two-sided collector with a high breakdown voltage and a low resistance collector. Additionally, the breakdown voltage can be modulated by the mask-to-emitter spacing for tuning finger-to-finger distances thereby affecting whether the scatter-implant lies in the active region of the respective devices.

Referring to FIG. 7E, a scatter-implant NPN ESD circuit 600 is shown. The scatter NPN ESD circuit 600 includes an input 605. Additionally, a first NPN transistor 610 has its collector connected to the input 605 and its base connected to a first resistor 615. A second side of the first resistor 615 is connected to the emitter of the first NPN transistor 610. Also, the collector of the first NPN transistor 610 is connected to the base of a second NPN transistor 625. The collector of the second NPN transistor 625 is connected to a first resistor.

In this example of a scatter-implant NPN ESD circuit, at least any one of the first NPN transistor 610 or second NPN transistor 625 may include a bi-level implant fabricated using a single step scatter-implant process. Advantages of the scatter-implant NPN ESD circuit 600 include a one-sided collector having a low breakdown and a relatively small element. Additionally, the circuit side of the scatter NPN ESD circuit 600 includes a two-sided collector having a high breakdown voltage and low resistance to the collector.

Referring to FIG. 7F, a scatter-implant variable trigger power clamp 700 is shown. The scatter-implant variable trigger power clamp 700 includes a first NPN transistor 710. The collector of the first NPN transistor 710 is connected to a string of diodes 715. This is electrically connected to an input node, or a power rail. The emitter of the first NPN transistor 710 is connected to a first resistor 720 and the base of a second NPN transistor 725. The base of the first NPN transistor 710 is the input of the circuit. The second NPN transistor 725 has its collector connected to the input end of the diode string 715 and it's emitter connected to a second resistor 730. The first resistor 720 and the second resistor 730 are connected to a ground rail or power rail. The first NPN transistor 710 forms the trigger section of the power clamp 700 and the second NPN transistor 725 forms the clamp section of the power clamp 700.

In this example of a scatter-implant ESD circuit 700, at least any one of the first NPN transistor 710 or second NPN transistor 725 includes a bi-level implant fabricated using a single step scatter-implant process. Advantages of the scatter-implant variable trigger power clamp circuit 700 include a trigger having a one-sided collector with a low breakdown voltage and relatively small size. Additionally, the clamp includes a two-sided collector with a high breakdown voltage and a low resistance collector having a lower resistance shunt.

While the invention has been described in terms of exemplary embodiments, those skilled in the art will recognize that the invention can be practiced with modifications and in the spirit and scope of the appended claims.

What is claimed is:

1. A method of adjusting a breakdown voltage of a semiconductor device, comprising the steps of:
providing a scattering edge proximate to a region to be scatter-implanted; and
passing a dose of ions through the scattering edge to scatter a predetermined portion of the dose of ions from the scattering edge into the region to be scatter-implanted to form a semiconductor device having an adjusted breakdown voltage.

2. The method of claim 1, wherein the region to be scatter-implanted comprises an active region of a semiconductor device.

3. The method of claim 1, wherein the region to be scatter-implanted is adjacent an emitter of a semiconductor device.

4. The method of claim 1, further comprising fabricating an electrostatic discharge device comprising the region to be scatter-implanted.

5. The method of claim 4, further comprising fabricating an NPN device comprising the region to be scatter-implanted in the electrostatic discharge device.

6. The method of claim 5, further comprising fabricating a variable trigger comprising the region to be scatter-implanted within the electrostatic discharge device.

7. The method of claim 1, further comprising fabricating at least any one of a semiconductor controlled rectifier, and a multi-finger tunable NPN circuit comprising the region to be scatter-implanted.

8. The method of claim 1, wherein the region to be scatter-implanted is adjacent an emitter of a semiconductor device.

9. The method of claim 1, wherein adjusting a breakdown voltage of a semiconductor device comprises scatter-implanting at least any one of a collector-emitter-base (CEB), collector-base-emitter (CBE), collector-emitter-base-emitter-collector (CEBEC), and collector-base-emitter-base-collector (CBEBC) semiconductor device configuration.

10. A method of forming a bi-level implanted semiconductor device, comprising the steps of:
arranging a scattering edge on a substrate;
forming a lower region of a bi-level implant by directing a first portion of a single dose of ions into a lower layer of the substrate; and
forming an upper region of the bi-level implant by directing a second portion of the single dose of ions into the scattering edge to scatter some ions of the second portion into an upper layer of the substrate.

11. The method of claim 10, wherein an upper region of the bi-level implant is configured to reduce the breakdown voltage of the bi-level implanted semiconductor device.

12. The method of claim 10, further comprising fabricating an electrostatic discharge device clamp comprising the bi-level implant.

13. The method of claim 12, further comprising fabricating an NPN device comprising the bi-level implant within the electrostatic discharge device.

14. The method of claim 13, further comprising fabricating a variable trigger comprising the bi-level implant within the electrostatic discharge device.

15. The method of claim 10, further comprising fabricating at least any one of a semiconductor controlled rectifier, and a multi-finger tunable NPN circuit comprising the bi-level implant.

16. A semiconductor device, comprising:
a substrate having ions of a single dose direct-implanted in the substrate at a lower level and ions of the single dose scatter-implanted in the substrate above the direct-implanted ions to form a scatter-implanted region in the substrate.

17. The semiconductor device of claim 16, wherein the ions scatter-implanted in the substrate above the direct-implanted ions are implanted in an active region of the semiconductor device.

18. The semiconductor device of claim 16, wherein the ions scatter-implanted in the substrate above the direct-implanted ions are implanted adjacent an emitter of the semiconductor device.

19. The semiconductor device of claim 16, comprising at least any one of a collector-emitter-base (CEB), collector-base-emitter (CBE), collector-emitter-base-emitter-collector (CEBEC), and collector-base-emitter-base-collector (CBEBC) semiconductor device configuration.

20. The semiconductor device of claim 16, wherein the semiconductor device comprising the scatter-implanted region is incorporated into an electrical circuit comprising at least any one of an NPN trigger electrostatic discharge (ESD) clamp, semiconductor controlled rectifier (SCR) with variable trigger, scatter circuit ESD, multi-finger tunable NPN circuit, NPN ESD circuit, and variable trigger power clamp.
